(19) United States
(12) Patent Application Publication
(10) Pub. No.: US 2024/0425723 A1
(43) Pub. Date: Dec. 26, 2024

(54) PAD-IN-A-BOTTLE CHEMICAL MECHANICAL PLANARIZATION POLISHING WITH COST-EFFECTIVE NON-POROUS SOLID POLISHING PADS

(71) Applicant: VERSUM MATERIALS US, LLC, TEMPE, AZ (US)

(72) Inventors: XIAOBO SHI, CHANDLER, AZ (US); JOHN G. LANGAN, TEMPE, AZ (US); MARK LEONARD O'NEILL, QUEEN CREEK, AZ (US); ROBERT VACASSY, PHOENIX, AZ (US); ARA PHILIPOSSIAN, TUCSON, AZ (US); YASA SAMPURNO, TUCSON, AZ (US); JAMES A. SCHLUETER, PHOENIX, AZ (US)

(21) Appl. No.: 18/704,699

(22) PCT Filed: Nov. 8, 2022
(86) PCT No.: PCT/US22/79452

§ 371 Date: Apr. 25, 2024

Related U.S. Application Data
(60) Provisional application No. 63/277,914, filed on Nov. 10, 2021.

(51) Int. Cl. C09G 1/02; H01L 21/321; H01L 23/48; H01L 23/532

(52) U.S. Cl. CPC C09G 1/02; H01L 21/3212; H01L 23/481; H01L 23/53228

(57) ABSTRACT

A novel pad-in-a-bottle (PIB) technology and PIB-type advanced chemical-mechanical planarization (CMP) Copper or THROUGH-SILICON VIA (TSV) CMP compositions, systems and processes have been disclosed. The role of conventional polishing pad asperities is played by high-quality micron-size polyurethane (PU) beads that are comparable to the sizes of pores and asperities in polishing pads. The less expensive non-porous, and solid polishing pads were less expensive, have been employed for reducing electronic device fabrication cost. There are benefits for using PIB-type Cu CMP slurries vs Non-PIB type Cu CMP slurries. Increased Cu removal rates at different applied down forces and sliding velocities, reduced Cu line dishing across different sized Cu line features and slightly reduced averaged COF have been observed using PIB-type Cu CMP slurries.

### CROSS REFERENCE TO RELATED PATENT APPLICATIONS

This application claims the benefit of priority under 35 U.S.C. § 119(e) to earlier filed U.S. patent application Ser. No. 63/277,914 filed on Nov. 10, 2021, which is entirely incorporated herein by reference.

### BACKGROUND OF THE INVENTION

This invention relates generally to a novel pad-in-a-bottle (PIB) technology and PIB type of advanced chemical-mechanical planarization (CMP) slurries, systems and processes. Specifically, present invention relates to PIB technology for using PIB type Cu and Through Silicon Vias (TSV) CMP slurries, systems and processes.

To reduce the cost of ownership on the expensive polyurethane polishing pads is very important for the semiconductor industry in CMP processes. In this invention, cost-effective non-porous solid polishing pads are used to replace the expensive porous polishing pads using PIB type of Cu and TSV CMP slurries.

In CMP, asperities on a polyurethane (PU) pad are irreversibly deformed due to wafer contact and are also abraded by composition particles. As such, the pad surface must be continuously renewed with a diamond disc to ensure process stability. Because diamond disk has to cut the pad surface to eliminate old asperities and create new ones, they also gradually thin the pad, forcing its replacement.

In Cu and TSV CMP, the porous on a polyurethane (PU) pad are needed to facilitate wafer contacts. In addition, the surface of the pad are constantly abraded by composition particles. As such, the pad surface must be continuously renewed with a diamond disc to ensure process stability. Because diamond disc has to cut the pad surface to eliminate old asperities and create new ones, which gradually thinning the pad, forcing its replacement.

Thus, conventional CMP has several weaknesses, such as (a) large amounts of waste is created (due to frequent replacement of pads and conditioners), (b) poorly controlled shapes of pad asperities that cause highly variable contact area distributions. These result in variations in removal rate (RR), and negatively affect wafer-level topography, among other things, and (c) large quantities and expensive polishing pads were consumed.

This invention discloses new novel pad-in-a-bottle (PIB) technology and the related PIB-type Cu CMP slurries for advanced node Copper and TSV CMP compositions, systems and processes developed using cost-effective and non-porous solid polishing pads to meet challenging requirements.

### BRIEF SUMMARY OF THE INVENTION

The needs are satisfied by using the disclosed compositions, methods, non-porous solid polishing pads and planarization systems for CMP of Copper and TSV substrates.

In one aspect, CMP polishing compositions is provided. The CMP polishing composition comprises:
abrasive particles;
micron-size polyurethane (PU) beads having a size ranging from 2 to 100 μm, 10 to 80 μm, 20 to 70 μm, or 30 to 50 μm;
silicone-containing dispersing agent;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 8.0; or 6.0 to 7.5.

In another aspect, CMP polishing method is provided. The CMP polishing method comprises:
providing the semiconductor substrate having a surface containing copper or THROUGH-SILICON VIA (TSV) copper;
providing a cost effective and non-porous solid polishing pad;
providing the chemical mechanical polishing (CMP) formulation stated above;
contacting the surface of the semiconductor substrate with the non-porous solid polishing pad and the chemical mechanical polishing formulation; and
polishing the surface of the semiconductor;
wherein at least a portion of the surface containing Cu film is in contact with both polishing pad and the chemical mechanical polishing formulation.

In yet another aspect, CMP polishing system is provided. The CMP polishing system comprises:
a semiconductor substrate having a surface containing copper or THROUGH-SILICON VIA (TSV) copper;
providing a non-porous, cost-effective and solid polishing pad;
providing the PIB-type chemical mechanical polishing (CMP) formulation in claim stated above;
wherein at least a portion of the surface containing Cu film is in contact with both the solid polishing pad and the chemical mechanical polishing formulation.

The abrasive particles are nano-sized particles, include, but are not limited to, colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide (ceria); colloidal cerium oxide; zirconium oxide (zirconia), nano-sized diamond particles; nano-sized silicon nitride particles; mono-modal, bi-modal, or multi-modal colloidal abrasive particles; organic polymer-based soft abrasives; surface-coated or modified abrasives; and mixtures thereof; or other composite particles, and mixtures thereof.

The preferred abrasive particles are colloidal silica.

The silicone-containing dispersing agent, includes, but is not limited to, silicone polyethers containing both a water-insoluble silicone backbone and a number of water-soluble polyether pendant groups; such as the repeating units of ethylene oxide (EO) and propylene oxide (PO) (EO-PO) functional groups to provide surface wetting properties.

The corrosion inhibitors include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The chelating agents (or chelators) include, but are not limited to, amino acids, amino acid derivatives, organic amines.

The amino acids and amino acid derivatives include, but not limited to, glycine, D-alanine, L-alanine, DL-alanine, beta-alanine, valine, leucine, isoleucine, phenylamine, proline, serine, threonine, tyrosine, glutamine, asparanine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The biocide includes but is not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof.

The organic quaternary ammonium salt as Cu removal rate boosting agent and defect reducing agent, includes, but is not limited to, choline salts with different counter ions, such as choline bicarbonate, choline hydroxide, choline dihydrogencitrate salt, choline ethanolamine, choline bitartrate, etc.

The pH adjusting agents include, but are not limited to, the following: nitric acid, hydrochloric acid, sulfuric acid, phosphoric acid, other inorganic or organic acids, and mixtures thereof. pH adjusting agents also include the basic pH adjusting agents, such as sodium hydroxide, potassium hydroxide, ammonium hydroxide, tetraalkyl ammonium hydroxide, organic amines, and other chemical reagents that are able to be used to adjust pH towards the more alkaline direction.

### DETAILED DESCRIPTION OF THE INVENTION

The current application discloses the PIB-type Cu CMP slurries where the cost-effective non-porous solid pads can be used in Cu CMP processes where the role of pad asperities is played by high-quality micron-size polyurethane (PU) beads having a size ranging from 2 to 100 μm, 10 to 80 μm, 20 to 70 μm, or 30 to 50 μm; that are comparable to the sizes of pores and asperities in commercial polishing pads.

The beads are suspended in a Cu CMP polishing composition having abrasive particles, such as a calcined ceria, colloidal silica, or composite particles with the assistance of a dispersing agent to disperse polyurethane beads in aqueous compositions.

The beads come into contact with the wafer surface by a means described below to promote polishing in much the same way as conventional asperities.

By selecting both the size of the beads, and their concentration in the composition, much better control of the height, curvature, and area density of the “summits” that come in contact with the wafer are achieved, substantially reducing the process variability associated with conventional asperity contact.

Use of beads still requires a second surface, or counter-face, for polishing to occur, which in our case continues to be a conventional polyurethane-based pad, but one that requires minimal conditioning as it is no longer the primary surface where polishing takes place. Alternatively, one can use an inexpensive and partially conditioned pad as the counter-face.

A polisher may use 2 to 3 pads and conditioners simultaneously. End-of-life for a pad and a conditioning disc is typically reached after only 2 days of continuous use. Each platen in a CMP tool, therefore, uses hundreds of pads and conditioners annually, and since wafer fabrication facilities can have dozens of tools (with 2 or 3 platens on each tool), the total cost for pads and pad conditioners alone is substantial. Therefore, using very cost-effective non-porous solid pads to replace porous and expensive polishing pads provide significant cost reductions in semiconductor device fabrication processes.

Since it can take several hours to remove a used pad, install, and qualify a new one, the engineering and product loss due to tool downtime and consumables used to qualify the new pad are also significant. Used PU pads and discarded diamond disc conditioners represent waste from the CMP processes which causes some environmental health and safety (EHS) issues.

As for a polishing pad, only about two-thirds of a pad thickness is used before the pad has to be stripped and discarded. For conditioner, only a few hundred diamonds out of tens of thousands control the product lifetime, after which the conditioner must be discarded. Furthermore, recycle or reuse options are not available for pads and conditioners. Our work addresses the above EHS issues and offers a novel solution to the current standard CMP processes by eliminating the use of lots of pads and diamond disc conditioners.

Polyurethane beads used in the disclosed polishing compositions have a size ranging from 2 to 100 μm, 10 to 80 μm, 20 to 70 μm, or 30 to 50 μm.

Several specific aspects of the present invention are outlined below.

In one aspect, CMP polishing compositions is provided.

Aspect 1: A CMP polishing composition comprising:
abrasives,
micron-size polyurethane (PU) beads;
silicone-containing dispersing agent;
liquid carrier such as water;
and optionally
a chelating agent or dual chelating agents or tris chelating agents;
corrosion inhibitor;
organic quaternary ammonium salt;
a biocide;
pH adjuster;
an oxidizer added at the point of use; and
the pH of the composition is from 3.0 to 12.0; 4.0 to 10.0; 5.5 to 8.0; or 6.0 to 7.5.

Aspect 2: A CMP polishing method comprising steps of:
providing the semiconductor substrate having a surface containing Copper or TSV Copper;
providing a non-porous, solid and cost-effective polishing pad;
providing the chemical mechanical polishing (CMP) formulation stated above;
contacting the surface of the semiconductor substrate with the non-porous solid polishing pad and the chemical mechanical polishing formulation; and
polishing the surface of the semiconductor;
wherein at least a portion of the surface containing Cu film is in contact with both polishing pad and the chemical mechanical polishing formulation.

Aspect 3: A CMP polishing system comprises:
a semiconductor substrate having a surface containing Cu film;
providing a non-porous, less expensive and solid polishing pad;
providing the chemical mechanical polishing (CMP) formulation in claim stated above;
wherein at least a portion of the surface containing Cu film is in contact with both the polishing pad and the chemical mechanical polishing formulation.

The abrasive particles are nano-sized particles, include, but are not limited to, colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide (ceria); colloidal cerium oxide; zirconium oxide (zirconia), nano-sized diamond particles; nano-sized silicon nitride particles; mono-modal, bi-modal, or multi-modal colloidal abrasive particles; organic polymer-based soft abrasives; surface-coated or modified abrasives; and mixtures thereof; or other composite particles, and mixtures thereof.

The preferred abrasive particles are colloidal silica. The colloidal silica can be made from silicate salts, the high purity colloidal silica can be made from TEOS or TMOS. The colloidal silica or high purity colloidal silica can have narrow or broad particle size distributions with mono-model or multi-models, various sizes and various shapes including spherical shape, cocoon shape, aggregate shape and other shapes.

The nano-sized particles also can have different shapes, such as spherical, cocoon, aggregate, and others.

The particle size of the abrasives used in the Cu CMP slurries is ranged from 5 nm to 500 nm, 10 nm to 250 nm, or 25 nm to 100 nm.

The Cu CMP polishing compositions comprise 0.0025 wt. % to 25 wt. % abrasives; 0.0025 wt. % to 2.5 wt. %; or 0.005 wt. % to 1.5 wt. % of abrasives.

The CMP polishing compositions comprise silicone-containing dispersing agent to disperse the polyurethane beads in aqueous solutions. The silicone-containing dispersing agent also functions as a surface wetting agent dispersing agent.

The silicone-containing dispersing agent, includes, but is not limited to, silicone polyethers containing both a water-insoluble silicone backbone and a number of water-soluble polyether pendant groups; such as the repeating units of EO-PO functional groups to provide surface wetting properties.

Examples of the silicone-containing dispersing agent includes Silsurf® E608, Silsurf® J208-6, Silsurf® A208, Silsurf® CR1115, Silsurf® A204, Silsurf® A004-UP, Silsurf® A008-UP, Silsurf® B608, Silsurf® C208, Silsurf® C410, Silsurf® D208, Silsurf® D208, Silsurf® D208-30, Silsurf® Di-1010, Silsurf® Di-1510, Silsurf® Di-15-I, Silsurf® Di-2012, Silsurf® Di-5018-F, Silsurf® G8-I, Silsurf® J1015-O, Silsurf® J1015-O-AC, Silsurf® J208, Silsurf® J208-6, Siltech® OP-8, Siltech® OP-11, Siltech® OP-12, Siltech® OP-15, Siltech® OP-20; the products from Siltech Corporation; 225 Wicksteed Avenue, Toronto Ontario, Canada M4H 1G5.

The concentration range of the silicone-containing dispersing agent is from 0.001 wt. % to 2.0 wt. %, 0.002 to 1.0 wt. %, or 0.005 wt. % to 0.5 wt. %.

The CMP slurry contains various sized polyurethane beads.

The concentration range of the polyurethane beads is from 0.01 wt. % to 2.0 wt. %, 0.025 wt. % to 1.0 wt. %, or 0.05 wt. % to 0.5 wt. %.

The organic quaternary ammonium salt as Cu removal rate boosting agent and defect reducing agent, includes but is not limited to choline salt, such as choline bicarbonate salt, or all other salts formed between choline and other anionic counter ions.

The CMP slurry contains 0.005 wt. % to 0.5 wt. %, 0.001 wt. % to 0.25 wt. %; or 0.002 wt. % to 0.1 wt. % of quaternary ammonium salt.

The chelating agents (or chelators) include, but are not limited to, amino acids, amino acid derivatives, organic amines.

The amino acids and amino acid derivatives include, but not limited to, glycine, D-alanine, L-alanine, DL-alanine, beta-alanine, valine, leucine, isoleucine, phenylamine, proline, serine, threonine, tyrosine, glutamine, asparanine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The CMP slurry contains 0.1 wt. % to 18 wt. %; 0.5 wt. % to 15 wt. %; or 1.0 wt. % to 10.0 wt. % of at least one chelator, dual chelators or tris chelators.

The corrosion inhibitors can be any known reported corrosion inhibitors.

The corrosion inhibitors for example, include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The CMP slurry contains 0.001 wt. % to 1.0 wt. %; 0.005 wt. % to 0.5 wt. %; or 0.01 wt. % to 0.25 wt. % of corrosion inhibitor.

A biocide having active ingredients for providing more stable shelf time of the Cu chemical mechanical polishing compositions can be used.

The biocide includes but is not limited to Kathon™, Kathon™ CG/ICP II, from Dow Chemical Co. They have active ingredients of 5-chloro-2-methyl-4-isothiazolin-3-one and/or 2-methyl-4-isothiazolin-3-one.

The CMP slurry contains 0.0001 wt. % to 0.05 wt. %; 0.0001 wt. % to 0.025 wt. %; or 0.0001 wt. % to 0.01 wt. % of biocide.

Acidic or basic compounds or pH adjusting agents can be used to allow pH of CMP polishing compositions being adjusted to the optimized pH value,

The pH adjusting agents include, but are not limited to, the following: nitric acid, hydrochloric acid, sulfuric acid, phosphoric acid, other inorganic or organic acids, and mixtures thereof; and other chemical reagents that are able to be used to adjust pH towards the more acidic direction. pH adjusting agents also include the basic pH adjusting agents, such as sodium hydroxide, potassium hydroxide, ammonium hydroxide, tetraalkyl ammonium hydroxide, organic amines, and other chemical reagents that are able to be used to adjust pH towards the more alkaline direction.

The CMP slurry contains 0 wt. % to 1 wt. %; 0.01 wt. % to 0.5 wt. %; or 0.1 wt. % to 0.25 wt. % of pH adjusting agent.

pH of the Cu polishing compositions is from about 3.0 to about 12.0; preferred pH range is from 5.5 to 8.0; and the most preferred pH range is from 6.0 to 7.5.

Various per-oxy inorganic or organic oxidizing agents or other types of oxidizing agents can be used to oxidize the metallic copper film to the mixture of copper oxides to allow their quick reactions with chelating agents and corrosion inhibitors.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof. The preferred oxidizer is hydrogen peroxide.

The CMP composition contains 0.1 wt. % to 10 wt. %; 0.25 wt. % to 7 wt. %; or 0.5 wt. % to 5.0 wt. % of oxidizing agents.

### EXPERIMENTAL SECTION

### Parameters:

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min

### Removal Rates (RR):

Cu RR 1.5 psi Measured Copper removal rate at 1.5 psi down pressure of the CMP tool
Cu RR 2.5 psi Measured Copper removal rate at 2.5 psi down pressure of the CMP tool
Cu RR 3.5 psi Measured Copper removal rate at 3.5 psi down pressure of the CMP tool

### General Experimental Procedure

All percentages in the compositions are weight percentages unless otherwise indicated.

In the examples presented below, CMP experiments were run using the procedures and experimental conditions given below. The CMP tool that was used in the examples is a 300 mm APD-800® polisher, manufactured by Fujikoshi Machinary Corporation (Nagano Japan). Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by Planarization Platform of Versum Materials, Inc. at baseline conditions. Polishing experiments were conducted using blanket Cu wafers with and Cu MIT854 200 mm patterned wafers. These blanket wafers were purchased from Silicon Valley Microelectronics, 1150 Campbell Ave, CA, 95126.

Polishing pad, non-porous solid CH34 pad or CH52 pad, supplied by Kuraray Corporation in Japan was used on the platen for the blanket wafer polishing studies. Polishing pad, non-porous solid pad TWI 312HTG, supplied by Thomas West Inc. located at 470 Mercury Drive, Sunnyvale, CA 94085, USA, was used on the platen for the blanket wafer polishing studies.

### Working Example

The reference (Ref.) Non-PIB Cu CMP polishing composition comprised of 5.20 wt. % glycine, 2.40 wt. % alanine, 0.016 wt. % Amitrole, 0.0231 wt. % choline bicarbonate, 0.0016 wt. % Neolone M10 biocide, 0.2705 wt. % high purity colloidal silica particles, and 0.050 wt. % Silsurf E608 as dispersing agent.

Silsurf E608 containing EO-PO wetting functional groups was used as the silicone-containing dispersing agent.

The testing sample, PIB-type Cu CMP polishing composition comprised of 5.20 wt. % glycine, 2.40 wt. % alanine, 0.016 wt. % Amitrole, 0.0231 wt. % choline bicarbonate, 0.0016 wt. % Neolone M10 biocide, 0.2705 wt. % high purity colloidal silica particles, and 0.050 wt. % Silsurf E608 as dispersing agent, and 0.10 wt. % 35 micron sized polyurethane beads.

2.5 wt. % H₂O₂ was added into the CMP compositions at the point of use.

Both Reference and testing polishing compositions had a pH around 7.20.

Two non-porous, less-expensive, and solid CH34 and CH52 pads were used in the following examples. Examples 1 to 3 were performed on the first CH34 pad. Same measurements were done in Examples 4 to 6 using the second CH52 pad.

### Example 1 Cu Removal Using CH34 Non-Porous Solid Pad

The Cu removal rates were tested using those Non-PIB and PIB-type Cu CMP polishing compositions and the first CH34 pad. The results were listed in Table 1.

TABLE 1
Cu Removal Rate Comparison in Cu Compositions with CH34 Pad

| Polishing | | Non-PIB Ref. | PIB-Cu Slurry | Cu RR |
|---|---|---|---|---|
| Pressure | Sliding | Cu Slurry Cu | Cu RR | Change |
| (PSI) | Velocity | RR (Å/min.) | (Å/min.) | % |
| 1.5 | 1 | 6,317 | 7,025 | (+11.2%) |
| | 1.6 | 7,881 | 8,288 | (+5.2%) |
| | 2.2 | 8,879 | 10,228 | (+16.0%) |
| 2.5 | 1 | 9,167 | 10,407 | (+13.5%) |
| | 1.6 | 11,594 | 12,693 | (+9.5%) |
| | 2.2 | 13,949 | 15,138 | (+8.6%) |
| 3.5 | 1 | 11,967 | 13,226 | (+10.5%) |
| | 1.6 | 15,456 | 16,831 | (+8.9%) |
| | 2.2 | 18,620 | 20,473 | (+10.0%) |

As the Cu removal rate results shown in Table 1, the Cu removal rates were increased for PIB-Cu polishing composition vs Non-PIB Cu polishing composition under three different applied down forces times three different sliding velocities which demonstrated one key benefit of using PIB-type Cu polishing composition on less expensive non-porous solid polishing pad vs Non-PIB Cu polishing composition.

### Example 2 Coefficient of Friction Using CH34 Non-Porous Solid Pad

The coefficient of friction (COF) using those Non-PIB and PIB-type Cu CMP polishing compositions, and the results were compared in Table 2.

TABLE 2
COF Comparison in Cu Compositions with CH34 Pad

| Polishing | | Non-PIB | PIB-Cu | COF |
|---|---|---|---|---|
| Pressure | Sliding | Ref. | Slurry | Change |
| (PSI) | Velocity | Mean COF | Mean COF | % |
| 1.5 | 1 | 0.38 | 0.371 | (−2.4%) |
| | 1.6 | 0.374 | 0.366 | (−2.1%) |
| | 2.2 | 0.361 | 0.37 | (+2.5%) |
| 2.5 | 1 | 0.406 | 0.382 | (−5.9%) |
| | 1.6 | 0.371 | 0.363 | (−2.2%) |
| | 2.2 | 0.359 | 0.36 | same |
| 3.5 | 1 | 0.421 | 0.399 | (−5.2%) |
| | 1.6 | 0.367 | 0.365 | (−0.50%) |
| | 2.2 | 0.358 | 0.358 | same |

As the COF comparison results shown in Table 2, the COF were reduced for PIB-Cu polishing composition vs Non-PIB Cu polishing composition under three different applied down forces times three different sliding velocities which demonstrated another key benefit of using PIB-type Cu polishing composition on less expensive non-porous solid polishing pad vs Non-PIB Cu polishing composition.

### Example 3 Cu Dishing Using CH34 Non-Porous Solid Polishing Pad

The 200 mm Cu patterned wafers were polishing using Non-PIB Cu polishing composition as Reference sample and PIB-type Cu polishing composition as testing sample under 2.5 psi down force and 1.6 m/s sliding velocity conditions.

The Cu line dishing comparison on six different sized Cu line features were compared in Table 3.

TABLE 3
Cu Dishing Comparison in Cu Compositions with CH34 Pad

| DF(PSI) & | | Non-PIB | PIB-Cu | |
|---|---|---|---|---|
| Sliding | | Ref. | Slurry | Cu Dishing |
| Velocity | | Cu Dishing | Cu Dishing | Change |
| (m/s) | Cu Line Size | (Å) | (Å) | % |
| 2.5/1.6 | 100 × 100 μm | 2588 | 2211 | (−14.6%) |
| | 50 × 50 μm | 2477 | 1997 | (−19.4%) |
| | 9 × 1 μm | 2191 | 1733 | (−20.9%) |
| | 10 × 10 μm | 1743 | 1403 | (−19.5%) |
| | 1 × 9 μm | 1510 | 1307 | (−13.5%) |
| | 1 × 1 μm | 1674 | 1530 | (−8.6%) |

As the Cu line dishing comparison results shown in Table 3, the Cu line dishing were reduced for PIB-Cu polishing composition vs Non-PIB Cu polishing composition across all six different Cu line features which demonstrated the third key benefit of using PIB-type Cu polishing composition on less expensive non-porous solid polishing pad vs Non-PIB Cu polishing composition to achieving lower Cu line dishing performances with PIB-type Cu CMP slurries.

In general, using non-porous, less-expensive, and non-porous solid CH34 polishing pad, PIB-type Cu CMP polishing composition provided the higher Cu film removal rates, slightly lower averaged COF, and reduced Cu line dishing across all tested Cu Line features than that from Non-PIB Cu polishing composition.

### Example 4 Cu Removal Using CH52 Non-Porous Solid Pad

The Cu removal rates were tested using those two Non-PIB and PIB-type Cu CMP polishing compositions on another non-porous, less-expensive, and the second non-porous solid CH52 pad. The results were listed in Table 4.

TABLE 4
Cu Removal Rate Comparison in Cu Compositions with CH52 Pad

| Polishing | | Non-PIB Ref. | PIB-Cu Slurry | Cu RR |
|---|---|---|---|---|
| Pressure | Sliding | Cu Slurry Cu | Cu RR | Change |
| (PSI) | Velocity | RR (Å/min.) | (Å/min.) | % |
| 1.5 | 1 | 7,195 | 7,861 | (+9.3%) |
| | 1.6 | 8,740 | 9,684 | (+10.8%) |
| | 2.2 | 10,119 | 11,269 | (+11.4%) |
| 2.5 | 1 | 10,648 | 11,504 | (+8.0%) |
| | 1.6 | 13,323 | 14,140 | (+6.1%) |
| | 2.2 | 15,422 | 16,713 | (+8.4%) |
| 3.5 | 1 | 13,698 | 14,563 | (+6.3%) |
| | 1.6 | 17,574 | 18,310 | (+4.2%) |
| | 2.2 | 22,064 | 22,763 | (+3.2%) |

As the Cu removal rate results shown in Table 4, using the second CH52 pad, Table 4 gave the consistent results using the second CH52 pad as those Cu removal rate results obtained using the first CH34 pad.

### Example 5 Coefficient of Friction Using CH52 Non-Porous Solid Pad

The coefficient of friction (COF) using those two Non-PIB and PIB-type Cu CMP polishing compositions with CH52 polishing pad were compared, and the results were compared in Table 5.

TABLE 5
COF Comparison in Cu Compositions with CH52 Pad

| Polishing | | | | |
|---|---|---|---|---|
| Pressure | Sliding | Non-PIB Ref. | PIB-Cu Slurry | COF |
| (PSI) | Velocity | Mean COF | Mean COF | Change % |
| 1.5 | 1 | 0.353 | 0.339 | (−4.0%) |
| | 1.6 | 0.358 | 0.35 | (−2.2%) |
| | 2.2 | 0.358 | 0.362 | (+1.1%) |
| 2.5 | 1 | 0.386 | 0.37 | (−4.1%) |
| | 1.6 | 0.355 | 0.355 | same |
| | 2.2 | 0.349 | 0.356 | (+2.0%) |
| 3.5 | 1 | 0.394 | 0.38 | (−3.6%) |
| | 1.6 | 0.358 | 0.353 | (−1.4%) |
| | 2.2 | 0.35 | 0.349 | same |

As the COF comparison results shown in Table 2 using the first CH52 pad, Table 5 gave the consistent results using the second CH52 polishing pad as those Cu coefficient of friction results obtained using the first CH34 pad.

### Example 6 Cu Dishing Using CH52 Non-Porous Solid Pad

The 200 mm Cu patterned wafers were polishing using Non-PIB Cu polishing composition as Reference sample and PIB-type Cu polishing composition as testing sample under 2.5 psi down force and 1.6 m/s sliding velocity conditions using the second non-porous solid CH52 polishing pad.

The Cu line dishing comparison on six different sized Cu line features were compared in Table 6.

TABLE 6
Cu Dishing Comparison in Cu Compositions with CH52 Pad

| DF(PSI) & | | | | |
|---|---|---|---|---|
| Sliding | | Non-PIB Ref. | PIB-Cu Slurry | |
| Velocity | | Cu Dishing | Cu Dishing | Cu Dishing |
| (m/s) | Cu Line Size | (Å) | (Å) | Change % |
| 2.5/1.6 | 100 × 100 μm | 2198 | 1846 | (−14.0%) |
| | 50 × 50 μm | 1978 | 1659 | (−16.1%) |
| | 9 × 1 μm | 1559 | 1400 | (−11.2%) |
| | 10 × 10 μm | 1337 | 1209 | (−9.6%) |
| | 1 × 9 μm | 1340 | 1131 | (−15.4%) |
| | 1 × 1 μm | 1398 | 1278 | (−8.6%) |

As the Cu line dishing comparison results shown in Table 6 using the second CH52 pad, Table 6 gave the consistent results using the second CH52 solid polishing pad as those Cu line dishing results obtained using the first CH34 pad.

### Example 7 Cu Removal Using TWI 312HTG Non-Porous Solid Pad

The Cu removal rates were tested using those two Non-PIB and PIB-type Cu CMP polishing compositions on the third non-porous, less-expensive, and solid Thomas West CMP polishing pad (TWI 312HTG). The results were listed in Table 7.

TABLE 7
Cu Removal Rate Comparison in Cu Compositions with
TWI 312HTG Pad

| Polishing | | Non-PIB Ref. | PIB-Cu Slurry | |
|---|---|---|---|---|
| Pressure | Sliding | Cu Slurry Cu | Cu RR | Cu RR |
| (PSI) | Velocity | RR (Å/min.) | (Å/min.) | Change % |
| 1.5 | 1 | 6,783 | 8,089 | (+19.3%) |
| | 1.6 | 8,796 | 10,315 | (+17.3%) |
| | 2.2 | 10,722 | 11,913 | (+11.1%) |
| 2.5 | 1 | 10,247 | 10.972 | (+7.1%) |
| | 1.6 | 14,684 | 14,714 | (+0.2%) |
| | 2.2 | 17,241 | 17,723 | (+2.8%) |
| 3.5 | 1 | 13,494 | 14,399 | (+6.7%) |
| | 1.6 | 19,177 | 19,714 | (+2.8%) |
| | 2.2 | 24,324 | 25,017 | (+2.8%) |

As the Cu removal rate results shown in Table 7 using the third Thomas West polishing pad, Cu removal rates were increased significantly at 1.5 psi down force and under different sliding velocity conditions.

### Example 8 Coefficient of Friction Using TWI 31 2HTG Non-Porous Solid Pad

The coefficient of friction (COF) using those two Non-PIB and PIB-type Cu CMP polishing compositions with TWI 312HTG polishing pad were compared, and the results were compared in Table 8.

TABLE 8
COF Comparison in Cu Compositions with TWI 312HTG Pad

| Polishing | | | | COF |
|---|---|---|---|---|
| Pressure | Sliding | Non-PIB Ref. | PIB-Cu Slurry | Change |
| (PSI) | Velocity | Mean COF | Mean COF | % |
| 1.5 | 1 | 0.370 | 0.349 | (−5.7%) |
| | 1.6 | 0.406 | 0.383 | (−5.7%) |
| | 2.2 | 0.407 | 0.399 | (−2.0%) |
| 2.5 | 1 | 0.395 | 0.371 | (−4.1%) |
| | 1.6 | 0.407 | 0.392 | (−3.7%) |
| | 2.2 | 0.404 | 0.395 | (−2.2%) |
| 3.5 | 1 | 0.423 | 0.396 | (−6.4%) |
| | 1.6 | 0.416 | 0.403 | (−3.1%) |
| | 2.2 | 0.403 | 0.394 | (−2.2%) |

As the COF comparison results shown in Table 8, using the third TWI 312HTG non-porous solid polishing pad, PIB-type Cu CMP slurry with polyurethane beads provided the reduced COF than the COF obtained from using Non-PIB Cu slurry without using polyurethane beads at nine different applied down form and sliding velocity combined conditions which clearly shown a key benefit of using PIB technology and PIB type Cu CMP slurries in Cu and TSV CMP polishing processes.

### Example 9 Cu Dishing Using TWI 312HTG Non-Porous Solid Pad

The 200 mm Cu patterned wafers were polishing using Non-PIB Cu polishing composition as Reference sample and PIB-type Cu polishing composition as testing sample under 2.5 psi down force and 1.6 m/s sliding velocity conditions using the third TWI 312HTG Non-Porous Solid Pad.

The Cu line dishing comparison on six different sized Cu line features were compared in Table 9.

TABLE 9
Cu Dishing Comparison in Cu Compositions with TWI 312HTG Pad

| DF(PSI) & | | Non-PIB | | |
|---|---|---|---|---|
| Sliding | | Ref. | PIB-Cu Slurry | Cu Dishing |
| Velocity | | Cu Dishing | Cu Dishing | Change |
| (m/s) | Cu Line Size | (Å) | (Å) | % |
| 2.5/1.6 | 100 × 100 μm | 2189 | 1832 | (−16.3%) |
| | 50 × 50 μm | 1765 | 1357 | (−23.1%) |
| | 9 × 1 μm | 1856 | 1341 | (−27.7%) |
| | 10 × 10 μm | 1616 | 1149 | (−28.9%) |
| | 1 × 9 μm | 1595 | 1142 | (−28.4%) |
| | 1 × 1 μm | 1887 | 1276 | (−32.4%) |

As the Cu line dishing comparison results shown in Table 9, using the third TWI 312HTG Non-Porous Solid Pad, PIB-type Cu CMP slurry with polyurethane beads provided the significantly reduced Cu line dishing across all six tested Cu line features than the Cu line dishing obtained from using Non-PIB Cu slurry without using polyurethane beads which clearly shown a key benefit of using PIB technology and PIB type Cu CMP slurries in Cu and TSV CMP polishing processes for achieving the enhanced Cu removal rates and at the same getting much lower Cu line dishing.

In summary, this invention by using non-porous, less-expensive, and solid CH34 or CH52 polishing pad, PIB-type Cu CMP polishing composition provided the higher Cu film removal rates, slightly lower averaged COF, and reduced Cu line dishing across all tested Cu Line features than that from Non-PIB Cu polishing composition.

The above listed results have shown one of the benefits of using micron sized PU beads in PIB-type Cu CMP compositions, the Cu removal rates can be increased using non-porous, less-expensive, and solid polishing pads.

Clearly, PIB-type Cu CMP polishing composition containing PU beads outperforms the Cu polishing compositions without using PU beads with non-porous, less-expensive, and solid polishing pads.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical mechanical polishing (CMP) composition comprising:
abrasives,
micron-size polyurethane (PU) beads ranging from 2 to 100 μm, or 20 to 70 μm;
silicone-containing dispersing agent;
at least one chelating agent;
corrosion inhibitor;
and optionally
organic quaternary ammonium salt;
a biocide;
pH adjuster;
an oxidizer added at the point of use;
liquid carrier such as water; and
the pH of the composition is from 3.0 to 12.0; or 5.5 to 8;
wherein the chelating agent is selected from the group consisting of amino acid, amino acid derivative, organic amine, and combinations thereof.

2. The CMP composition of claim 1, wherein the abrasives are selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; zirconium oxide, nano-sized diamond particles; nano-sized silicon nitride particles; mono-modal, bi-modal, or multi-modal colloidal abrasive particles; organic polymer-based soft abrasives; surface-coated or modified abrasives; and combinations thereof; and the abrasives range from 0.0025 wt. % to 25 wt. % or 0.0025 wt. % to 2.5 wt. % and the micron-size polyurethane (PU) beads range from 0.01 wt. % to 2.0 wt. %, or 0.025 wt. % to 1.0 wt. %.

3. (canceled)

4. The CMP composition of claim 1, wherein the silicone-containing dispersing agent comprises a silicone polyether containing both a water-insoluble silicone backbone and a number of water-soluble polyether pendant groups including repeating units of ethylene oxide (EO) and propylene oxide (PO) (EO-PO) functional groups; and the silicone-containing dispersing agent ranges from 0.01 wt. % to 2.0 wt. %, or 0.001 wt. % to 2.0 wt. %.

5. The CMP composition of claim 1, wherein the at least one chelating agent is selected from the group consisting of glycine, D-alanine, L-alanine, DL-alanine, beta-alanine, valine, leucine, isoleucine, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and the at least one chelating agent ranges from 0.1 wt. % to 18 wt. %; or 0.5 wt. % to 15 wt. %.

6. The CMP composition of claim 1, wherein the corrosion inhibitor is selected from the group consisting of family of hetero aromatic compounds containing nitrogen atom(s) in their aromatic rings, such as 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives; and the corrosion inhibitor ranges from 0.001 wt. % to 1.0 wt. %; or 0.005 wt. % to 0.5 wt. %.

7. The CMP composition of claim 1, wherein the biocide has an active ingredient selected from the group consisting of 5-chloro-2-methyl-4-isothiazolin-3-one, 2-methyl-4-isothiazolin-3-one, and combinations thereof; and the biocide ranges from 0.0001 wt. % to 0.05 wt. %; or 0.0001 wt. % to 0.025 wt. %.

8. The CMP composition of claim 1, wherein the oxidizing agent is selected from the group consisting of periodic acid, hydrogen peroxide, potassium iodate, potassium permanganate, ammonium persulfate, ammonium molybdate, ferric nitrate, nitric acid, potassium nitrate, and mixtures thereof; and the oxidizing agent ranges from 0.1 wt. % to 10 wt. %; or 0.25 wt. % to 7 wt. %.

9. The CMP composition of claim 1, wherein the organic quaternary ammonium salt is selected from the group consisting of choline salt having different counter ions selected from the group consisting of choline bicarbonate, choline hydroxide, choline dihydrogen citrate salt, choline ethanolamine, choline bitartrate, and combinations thereof; and the organic quaternary ammonium salt ranges from 0.005 wt. % to 0.5 wt. %, or 0.001 wt. % to 0.25 wt. %.

10. The CMP composition of claim 1, wherein the pH adjusting agent is selected from the group consisting of nitric acid, hydrochloric acid, sulfuric acid, phosphoric acid, other inorganic or organic acids, and other chemical reagents that are able to be used to adjust pH towards acidic direction; or is selected from the group consisting of sodium hydroxide, potassium hydroxide, ammonium hydroxide, tetraalkyl ammonium hydroxide, organic amines, and other chemical reagents that are able to be used to adjust pH towards alkaline direction.

11. (canceled)

12. The CMP composition of claim 1, wherein the CMP composition comprises at least one of chelating agent selected from the group consisting of glycine, glycine, D-alanine, L-alanine, DL-alanine, ethylenediamine, 1,3-diaminepropane, 1,4-diaminebutane, and combinations; the corrosion inhibitor is selected from the group consisting of 3-amino-1,2,4-triazole, 1,2,4-triazole, imidazole and imidazole derivatives, and combinations; choline bicarbonate or choline hydroxide; biocide; and colloidal silica particles; silicone-containing dispersing agent, and 30 to 50 μm polyurethane (PU) beads.

13. The CMP composition of claim 1, wherein the CMP composition comprises glycine and alanine, 3-amino-1,2,4-triazole, ethylenediamine, choline bicarbonate, biocide, and colloidal silica particles, silicone-containing dispersing agent, and 30 μm to 50 μm polyurethane (PU) beads.

14. A method of chemical mechanical polishing a semiconductor substrate, comprising steps of:
providing the semiconductor substrate having a surface containing Copper or Through Silicon Via (TSV) Copper;
providing a non-porous solid polishing pad;
providing a chemical mechanical polishing (CMP) composition comprising:
abrasives,
micron-size polyurethane (PU) beads ranging from 2 to 100 μm or 20 to 70 μm;
silicone-containing dispersing agent;
at least one chelating agent;
corrosion inhibitor;
and optionally
organic quaternary ammonium salt;
a biocide;
pH adjuster;
an oxidizer added at the point of use;
liquid carrier such as water; and
the pH of the composition is from 3.0 to 12.0; or 5.5 to 8;
wherein the chelating agent is selected from the group consisting of amino acid,
amino acid derivative, organic amine, and combinations thereof;
contacting the surface of the semiconductor substrate with the polishing pad and the chemical mechanical polishing composition; and
polishing the surface of the semiconductor;
wherein at least a portion of the surface containing copper or TSV copper is in contact with both the non-porous and solid polishing pad and the chemical mechanical polishing composition.

15. The method of claim 14, wherein
the abrasives in the CMP composition are selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide, colloidal cerium oxide; zirconium oxide, nano-sized diamond particles; nano-sized silicon nitride particles; mono-modal, bi-modal, or multi-modal colloidal abrasive particles; organic polymer-based soft abrasives; surface-coated or modified abrasives; and
mixtures thereof; and the abrasives range from 0.0025 wt. % to 25 wt. % or 0.0025 wt. % to 2.5 wt. %;
the micron-size polyurethane (PU) beads in the CMP composition range from 0.01 wt. % to 2.0 wt. % or 0.025 wt. % to 1.0 wt. %;
the silicone-containing dispersing agent in the CMP composition comprises a silicone polyether containing both a water-insoluble silicone backbone and water-soluble polyether Pendant groups including repeating units of ethylene oxide (EO) and propylene oxide (PO) (EO-PO) functional groups; and the silicone-containing dispersing agent ranges from 0.01 wt. % to 2.0 wt. % or 0.001 wt. % to 2.0 wt. %; and
the at least one chelating agent in the CMP composition is selected from the group consisting of glycine, D-alanine, L-alanine, DL-alanine, beta-alanine, valine, leucine, isoleucine, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and the at least one chelating agent ranges from 0.1 wt. % to 18 wt. % or 0.5 wt. % to 15 wt. %.

16. (canceled)

17. (canceled)

18. (canceled)

19. The method of claim 14, wherein
the corrosion inhibitor in the CMP composition is selected from the group consisting of family of hetero aromatic compounds containing nitrogen atom(s) in their aromatic rings, such as 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives; and the corrosion inhibitor ranges from 0.001 wt. % to 1.0 wt. % or 0.005 wt. % to 0.5 wt. %;
the biocide in the CMP composition has an active ingredient selected from the group consisting of 5-chloro-2-methyl-4-isothiazolin-3-one, 2-methyl-4-isothiazolin-3-one, and combinations thereof; and the biocide ranges from 0.0001 wt. % to 0.05 wt. % or 0.0001 wt. % to 0.025 wt. %;
the oxidizing agent in the CMP composition is selected from the group consisting of periodic acid, hydrogen peroxide, potassium iodate, potassium permanganate, ammonium Persulfate, ammonium molybdate, ferric nitrate, nitric acid, potassium nitrate, and mixtures thereof; and the oxidizing agent ranges from 0.1 wt. % to 10 wt. % or 0.25 wt. % to 7 wt. %;
the organic quaternary ammonium salt in the CMP composition is selected from the group consisting of choline salt having different counter ions selected from the group consisting of choline bicarbonate, choline hydroxide, choline dihydrogen citrate salt, choline ethanolamine, choline bitartrate, and combinations thereof; and the organic quaternary ammonium salt ranges from 0.005 wt. % to 0.5 wt. % or 0.001 wt. % to 0.25 wt. %; and
the pH adjusting agent in the CMP composition is selected from the group consisting of nitric acid, hydrochloric acid, sulfuric acid, phosphoric acid, other inorganic or organic acids, and other chemical reagents that are able to be used to adjust pH towards acidic direction; or is selected from the group consisting of sodium hydroxide, potassium hydroxide, ammonium hydroxide, tetraalkyl ammonium hydroxide, organic amines, and other chemical reagents that are able to be used to adjust pH towards alkaline direction.

20. (canceled)

21. (canceled)

22. (canceled)

23. (canceled)

24. (canceled)

25. The method of claim 14, wherein the CMP composition comprises at least one of chelating agent selected from the group consisting of glycine, glycine, D-alanine, L-alanine, DL-alanine, ethylenediamine, 1,3-diaminepropane, 1,4-diaminebutane, and combinations; the corrosion inhibitor is selected from the group consisting of 3-amino-1,2,4-triazole, 1,2,4-triazole, imidazole and imidazole derivatives, and combinations; choline bicarbonate or choline hydroxide; biocide; and colloidal silica particles; silicone-containing dispersing agent, and 30 to 50 μm polyurethane (PU) beads.

26. The method of claim 14, wherein the CMP composition comprises glycine and alanine, 3-amino-1,2,4-triazole, ethylenediamine, choline bicarbonate, biocide, and colloidal silica particles, silicone-containing dispersing agent, and 30 μm to 50 μm polyurethane (PU) beads.

27. A system of chemical mechanical polishing, comprising a semiconductor substrate having a surface containing copper or Through Vias (TSV) copper;
providing a non-porous solid polishing pad;
providing a chemical mechanical polishing (CMP) composition comprising:
abrasives,
micron-size polyurethane (PU) beads ranging from 2 to 100 μm or 20 to 70 μm;
silicone-containing dispersing agent;
at least one chelating agent;
corrosion inhibitor;
and optionally
organic quaternary ammonium salt;
a biocide;
pH adjuster;
an oxidizer added at the point of use;
liquid carrier such as water; and
the pH of the composition is from 3.0 to 12.0; or 5.5 to 8;
wherein the chelating agent is selected from the group consisting of amino acid,
amino acid derivative, organic amine, and combinations thereof;
wherein at least a portion of the surface containing copper or TSV copper is in contact with both the polishing pad and the chemical mechanical polishing composition.

28. The system of claim 27, wherein
the abrasives in the CMP composition are selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide, colloidal cerium oxide; zirconium oxide, nano-sized diamond particles; nano-sized silicon nitride particles; mono-modal, bi-modal, or multi-modal colloidal abrasive particles; organic polymer-based soft abrasives; surface-coated or modified abrasives; and mixtures thereof; and the abrasives range from 0.0025 wt. % to 25 wt. % or 0.0025 wt. % to 2.5 wt. %;
the micron-size polyurethane (PU) beads in the CMP composition range from 0.01 wt. % to 2.0 wt. % or 0.025 wt. % to 1.0 wt. %;
the silicone-containing dispersing agent in the CMP composition comprises a silicone polyether containing both a water-insoluble silicone backbone and water-soluble polyether pendant groups including repeating units of ethylene oxide (EO) and propylene oxide (PO) (EO-PO) functional groups; and the silicone-containing dispersing agent ranges from 0.01 wt. % to 2.0 wt. % or 0.001 wt. % to 2.0 wt. %; and
the at least one chelating agent in the CMP composition is selected from the group consisting of glycine, D-alanine, L-alanine, DL-alanine, beta-alanine, valine, leucine, isoleucine, phenylamine, proline, serine, threonine, tyrosine, glutamine, asparanine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and the at least one chelating agent ranges from 0.1 wt. % to 18 wt. % or 0.5 wt. % to 15 wt. %.

29. (canceled)

30. (canceled)

31. (canceled)

32. The system of claim 27, wherein
the corrosion inhibitor in the CMP composition is selected from the group consisting of family of hetero aromatic compounds containing nitrogen atom(s) in their aromatic rings, such as 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives; and the corrosion inhibitor ranges from 0.001 wt. % to 1.0 wt. % or 0.005 wt. % to 0.5 wt. %;
the biocide in the CMP composition has an active ingredient selected from the group consisting of 5-chloro-2-methyl-4-isothiazolin-3-one, 2-methyl-4-isothiazolin-3-one, and combinations thereof; and the biocide ranges from 0.0001 wt. % to 0.05 wt. % or 0.0001 wt. % to 0.025 wt. %;
the oxidizing agent in the CMP composition is selected from the group consisting of periodic acid, hydrogen peroxide, potassium iodate, potassium permanganate, ammonium Persulfate, ammonium molybdate, ferric nitrate, nitric acid, potassium nitrate, and mixtures thereof; and the oxidizing agent ranges from 0.1 wt. % to 10 wt. % or 0.25 wt. % to 7 wt. %;
the organic quaternary ammonium salt in the CMP composition is selected from the group consisting of choline salt having different counter ions selected from the group consisting of choline bicarbonate, choline hydroxide, choline dihydrogen citrate salt, choline ethanolamine, choline bitartrate, and combinations thereof; and the organic quaternary ammonium salt ranges from 0.005 wt. % to 0.5 wt. % or 0.001 wt. % to 0.25 wt. %; and
the pH adjusting agent in the CMP composition is selected from the group consisting of nitric acid, hydrochloric acid, sulfuric acid, phosphoric acid, other inorganic or organic acids, and other chemical reagents that are able to be used to adjust pH towards acidic direction; or is selected from the group consisting of sodium hydroxide, potassium hydroxide, ammonium hydroxide, tetraalkyl ammonium hydroxide, organic amines, and other chemical reagents that are able to be used to adjust pH towards alkaline direction.

33. (canceled)

34. (canceled)

35. (canceled)

36. (canceled)

37. (canceled)

38. The system of claim 27, wherein the CMP composition comprises at least one of chelating agent selected from the group consisting of glycine, glycine, D-alanine, L-alanine, DL-alanine, ethylenediamine, 1,3-diaminepropane, 1,4-diaminebutane, and combinations; the corrosion inhibitor is selected from the group consisting of 3-amino-1,2,4-triazole, 1,2,4-triazole, imidazole and imidazole derivatives, and combinations; choline bicarbonate or choline hydroxide; biocide; and colloidal silica particles; silicone-containing dispersing agent, and 30 to 50 μm polyurethane (PU) beads.

39. The system of claim 27, wherein the CMP composition comprises glycine and alanine, 3-amino-1,2,4-triazole, ethylenediamine, choline bicarbonate, biocide, and colloidal silica particles, silicone-containing dispersing agent, and 30 μm to 50 μm polyurethane (PU) beads.
